(19) United States
(12) Patent Application Publication
(10) Pub. No.: US 2015/0339418 A1
(43) Pub. Date: Nov. 26, 2015

(54) Modeling Radio Frequency Coverage

(71) Applicant: Ruckus Wireless, Inc., Sunnyvale, CA (US)

(72) Inventors: Warren BLACKWELL, San Jose, CA (US); Victor Shtrom, Los Altos, CA (US)

(21) Appl. No.: 14/814,681

(22) Filed: Jul. 31, 2015

Related U.S. Application Data
(63) Continuation of application No. PCT/US2014/014289, filed on Jan. 31, 2014.
(60) Provisional application No. 61/759,360, filed on Jan. 31, 2013.

(51) Int. Cl. G06F 17/50; H04W 16/18; G01R 29/10

(52) U.S. Cl. CPC G06F 17/5009; G01R 29/10; H04W 16/18

(57) ABSTRACT

Systems and methods of modeling a radio frequency (RF) coverage pattern by a processor according to some embodiments of the inventions here may include receiving coverage pattern data of an RF source and environment data where the RF source is placed, determining a set of obstructed coordinates of the coverage pattern based on a location of an obstacle between the RF source and a coverage pattern surface, and determining a modified RF coverage pattern of the RF source by modifying the set of obstructed coordinates based on an attenuation factor of the obstacle.

### CROSS REFERENCE TO RELATED APPLICATIONS

This application claims priority from and is a continuation of international PCT patent application PCT/US14/14289 filed 31 Jan. 2014 which claims priority from U.S. provisional patent application No. 61/759,360 filed 31 Jan. 2013, which are incorporated herein by reference in their entirety.

### TECHNICAL FIELD

This application relates to the field of radio frequency (RF) modeling, and more particularly to RF coverage visualization.

### BACKGROUND

Conventional RF modeling solutions, such as those provided by iBwave Solutions, calculate the effect of RF obstructions on an AP coverage pattern using computationally expensive methods such as ray tracing in order to provide a reasonably accurate estimation of the coverage pattern. A user may then use this model to optimize placement and configuration of a wireless system at a given location. However, these solutions sometimes suffer from the drawbacks of requiring more time and/or more expensive hardware to run, thereby limiting their use.

### SUMMARY

Radio frequency transmitting and receiving devices such as access points (AP) provide RF coverage based on factors particular to the device and the environment they are placed in.

Certain examples of the inventions here include methods and systems of modeling a radio frequency (RF) coverage pattern by a processor, including receiving coverage pattern data of an RF source and environment data where the RF source is placed, determining a set of obstructed coordinates of the coverage pattern based on a location of an obstacle between the RF source and a coverage pattern surface, and determining a modified RF coverage pattern of the RF source by modifying the set of obstructed coordinates based on an attenuation factor of the obstacle.

Further, certain examples may include embodiments where the coverage pattern data includes a plurality of vertices. Some examples include embodiments where a coordinate of the coverage pattern data is included in the set of obstructed coordinates when the obstacle intersects a line segment formed from the RF source to the coordinate. Embodiments may also include where the set of coordinates are moved towards the RF source.

Some examples may include embodiments including determining an attenuation factor of the obstacle based on at least one of shape, material and reflection. Certain embodiments may have the coverage pattern corresponding to at least one signal characteristic of an RF source including transmission signal strength, received signal strength, throughput, and reception sensitivity.

Example embodiments here may include a computer storage storing a sequence of instructions that, when executed by a computer processor, cause the computer processor to perform a method of modeling a radio frequency (RF) coverage pattern including receiving coverage pattern data of an RF source and environment data where the RF source is placed, determining a set of obstructed coordinates of the coverage pattern data based on an obstacle of the environment being between the RF source and the coverage pattern, and determining a modified RF coverage pattern of the RF source by changing the set of obstructed coordinates based on an attenuation factor of the obstacle.

Some examples may also include embodiments where the coverage pattern data includes a plurality of vertices. And certain embodiments may include embodiments where a coordinate of the coverage pattern data is included in the set of obstructed coordinates when the obstacle intersects a line segment formed from the RF source to the coordinate.

Some examples may have the set of coordinates moved towards the RF source. And some embodiments may determine an attenuation factor of the obstacle based on at least one of shape, material and reflection. Certain example embodiments may include embodiments wherein the coverage pattern corresponds to at least one signal characteristic of an RF source including transmission signal strength, received signal strength, throughput, and reception sensitivity.

Embodiments described here include a radio frequency (RF) coverage modeling system, including a processor configured to, determine a set of obstructed coordinates of the coverage pattern based on an obstacle of the environment being between an RF source and the coverage pattern and that determines a modified RF coverage pattern of the RF source by changing the set of obstructed coordinates based on an attenuation factor of the obstacle, receive coverage pattern data of an RF source and environment data where the RF source is placed, cause display of a user interface including information about the RF source, the environment and the RF coverage pattern.

Some embodiments may also include the processor is configured to cause display of two-dimensional perspective and a three-dimensional perspective. Some embodiments include the processor configured to receive at least one touch input, operation key input, voice input and motion input. Certain embodiments have the processor is further configured to receive input that modifies any of the RF source and the obstacles of the environment.

Certain examples here include embodiments where the processor is configured to redetermine the modified RF coverage pattern based on the modifications. And some embodiments include the processor further configured to determine the modified RF coverage pattern of a two-dimensional cross-section for the two-dimensional perspective. Some embodiments have the coverage pattern data of the RF source and the environment data received from another device over a communication network. And some embodiments include embodiments where the coverage pattern data includes a plurality of vertices.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1 is an illustrative three-dimensional (3D) coverage pattern for AP 102 according to some embodiments of the inventions.

FIG. 2 is a plurality of vertex data points 202 that define a coverage pattern analogous to coverage pattern 104 in FIG. 1 according to some embodiments of the inventions.

FIG. 3A is a two-dimensional (2D) coverage pattern 302 based on vertex data representative of a particular cross section of the coverage pattern according to some embodiments of the inventions.

FIG. 3B is a flow chart illustrative of example methods which may be used to implement some embodiments of the inventions.

FIG. 4 is a two-dimensional (2D) coverage pattern 400 based on vertex data representative of a particular cross section of the coverage pattern according to some embodiments of the inventions.

FIG. 5 is another three-dimensional (2D) coverage pattern 400 based on vertex data representative of a particular cross section of the coverage pattern according to some embodiments of the inventions.

FIG. 6 is another two-dimensional (2D) coverage pattern 400 based on vertex data representative of a particular cross section of the coverage pattern according to some embodiments of the inventions.

FIG. 7 is another three-dimensional (2D) coverage pattern 400 based on vertex data representative of a particular cross section of the coverage pattern according to some embodiments of the inventions.

FIG. 8 is another three-dimensional (2D) coverage pattern 400 based on vertex data representative of a particular cross section of the coverage pattern according to some embodiments of the inventions.

FIG. 9 is an illustrative block diagram of exemplar components which may be used to implement some embodiments of the inventions.

### DETAILED DESCRIPTION

Reference will now be made in detail to embodiments, examples of which are illustrated in the accompanying drawings. In the following detailed description, numerous specific details are set forth in order to provide a sufficient understanding of the subject matter presented herein. But it will be apparent to one of ordinary skill in the art that the subject matter may be practiced without these specific details. Moreover, the particular embodiments described herein are provided by way of example and should not be used to limit the scope of the invention to these particular embodiments. In other instances, well-known data structures, graphical user interface elements, software operations, procedures, and components have not been described in detail so as not to unnecessarily obscure aspects of the embodiments of the invention.

Although discussed in terms of wireless access points (AP), such as those implementing the 802.11 standard, one of ordinary skill will recognize that the concepts and examples discussed herein would equally apply to other types of RF devices implementing the same or different transmission protocols, or even no protocols.

Coverage Patterns

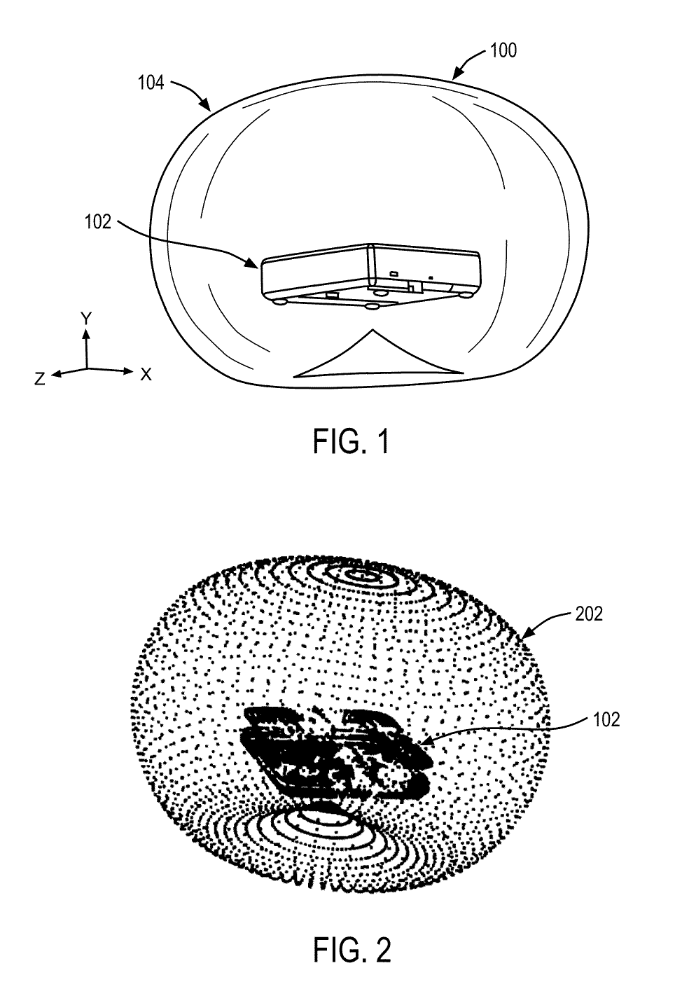

FIG. 1 provides an illustrative three-dimensional (3D) coverage pattern for an RF source/device such as a WiFi (e.g., 802.11) AP 102 according to some embodiments. The AP 102 generates a 3D coverage pattern 104 including coverage surface 100. The coverage pattern 104 represents any of a plurality of signal characteristics of an RF signal emanating from AP 102 such as a signal strength characteristic. The surface 100 and coverage pattern 104 may also be generated or selected to represent some other characteristic of the AP 102. For example, the coverage pattern 104 could be generated based on one or more of the following parameters including but not limited to signal strength, received signal strength indicator, throughput, transmission strength, reception sensitivity, some other characteristic and some combination of characteristics. Coverage patterns may differ for different types of RF devices and depend on any number of variables associated with the design of the RF device.

The example surface 100 is a representative level of a variable of any characteristic, used to help model the coverage. The surface 100 is shown as a three dimensional bubble as a representation only, and may vary depending on the modeling characteristic and variable used to calculate and determine coverage. Further, any number of example surfaces could be modeled, and any number of modeled surfaces could be displayed for reference. More than one surface could be used to help display differences in variables and/or characteristics. Still other examples could include a shading display, with different shades, patterns, textures, and/or colors depicting different variables and/or characteristics modeled. For example, there could be a color display showing a surface 100 that is a “satisfactory” coverage, such as a satisfactory signal strength. Other colors could represent unsatisfactory coverage or signal strength.

AP coverage patterns may be presented as 3D models in computer-aided design (CAD) software such as SolidWorks. Coverage pattern data may be exported from CAD software in one or more formats such as Virtual Reality Modeling Language (VRML). The VRML data, for example, may contain vertex data (vertices) and face definitions (face indices). VRML data may be converted into, for example, OpenGL ES compatible vertex and face index data and stored as a file. In some instances, there may be a file for each type of RF device and/or RF characteristic of the RF device.

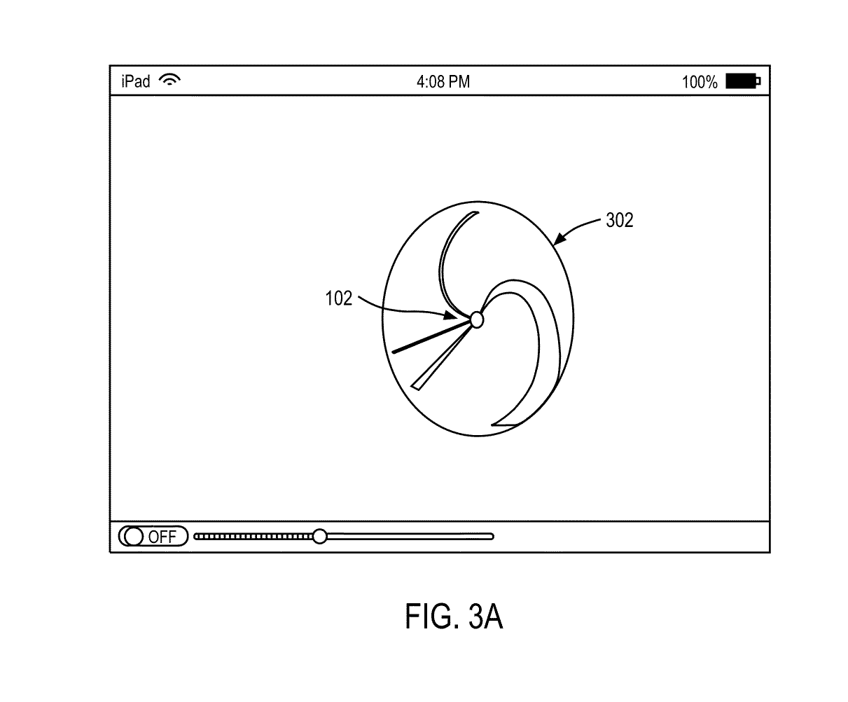

Vertex data may contain three numbers (x, y, z), with each number representing the three dimensional location of a point in space, relative to an arbitrary origin, along each of three axes. FIG. 2 illustrates a plurality of vertex data points 202 that define a coverage pattern analogous to coverage pattern 104 in FIG. 1 according to some embodiments. This vertex data can be drawn or represented on a display device using various rendering APIs including OpenGL ES.

RF planning is the process of assigning frequencies, transmitter locations and parameters of a wireless communications system to provide sufficient coverage and capacity for desired services. A user may input AP and environment/building characteristics into a device including floor plan, walls, cubicles, AP locations, etc., to predict RF coverage given the signal attenuation of the RF obstructions. For example, an RF signal passing through a wall of type “X” may attenuate so as to decrease the RF signal by “Y” decibels.

More Coverage Patterns

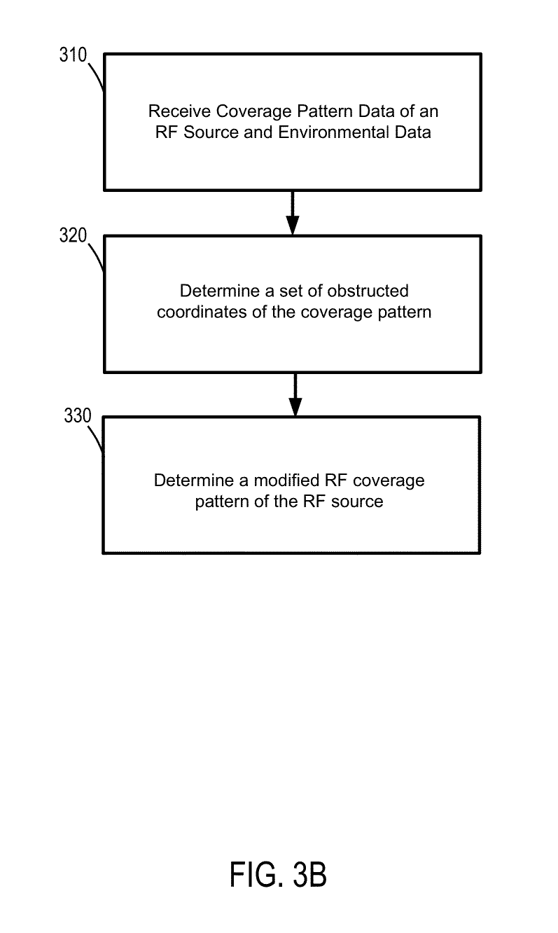

FIG. 3A illustrates a two-dimensional (2D) coverage pattern 302 based on vertex data representative of a particular cross section of the coverage pattern according to some embodiments. For example, FIG. 3A illustrates a cross-section of the coverage pattern 302 in the plane of the AP 102 from a plan view perspective of the AP 102. In certain embodiments, the coverage pattern 302 may tend toward a round or near round shape with respect to the AP 102 at the center corresponding to the omnidirectional nature of a particular signal propagation pattern. In certain embodiments, the display provides a coverage area for a plurality of characteristics of the AP 102. An antenna or coverage pattern of an RF source generally represents the ideal RF coverage (such as, by for example, measurements made in an anechoic chamber or using mathematical modeling) while a real coverage pattern incorporates the effect of the environment in which the RF source is placed.

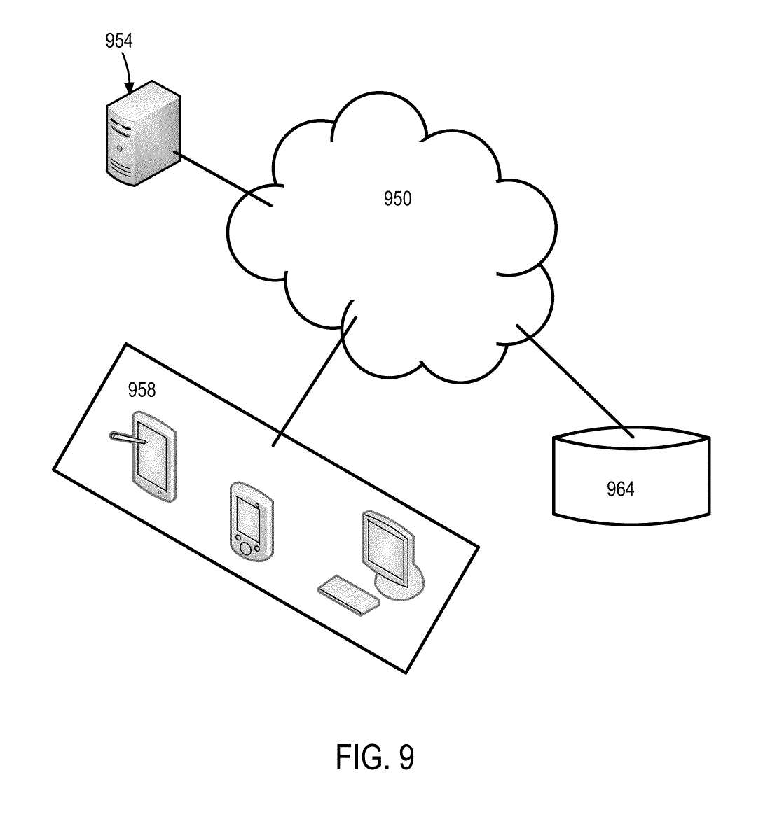

The coverage patterns illustrated herein may be displayed on any computing device including mobile devices and is not limited. Such a device may include hardware necessary to perform the functions associated with it, for example a computer processor, memory, display and the like, and may run on any operating system including mobile operating systems. In this disclosure, the term computing device may include, but is not limited to, any display device, for example smartphones, laptops, netbooks, ultrabooks, tablets, phablets, handheld computers, desktop computers, terminals, etc. Examples of such devices are discussed further in FIG. 9.

In certain embodiments, an RF coverage pattern of an RF source is determined and cause to be displayed based on vertex data corresponding to the coverage pattern and RF obstruction data. A method of determining RF coverage may include determining if a line segment formed from the RF source to each vertex data point intersects an RF obstacle. If so, the vertex data point is changed or modified to move closer to the RF source by an amount determined by an attenuation factor of the RF obstacle. The attenuation factor may be a function of one or more characteristics of the RF obstacle including the material composition of the RF obstacle and/or the characteristics of the RF environment including reflections of a signal within the RF environment or others signals. Any combination of factors affecting attenuation may be used to calculate the attenuation factor.

This process is repeated for every coverage pattern within a predetermined environment. FIG. 3B is flow chart illustrative of example methods which may be used to implement some embodiments of the inventions. Such example methods may include receiving coverage pattern data of an RF source and environmental data 310; determining a set of obstructed coordinates of the coverage pattern 320; and determining a modified RF coverage patter of the RF source by modifying the set of obstructed coordinates, based on the attenuation factor of the obstacle 330.

This method of signal propagation calculation may be more computationally efficient than prior art methods such as ray tracing. In this manner, the RF environment may be analyzed to shrink the coverage pattern model rather than computing the coverage pattern model from the environment. The coverage pattern may then be displayed based on the modified vertex data and may be viewed and manipulated as discussed in further detail below.

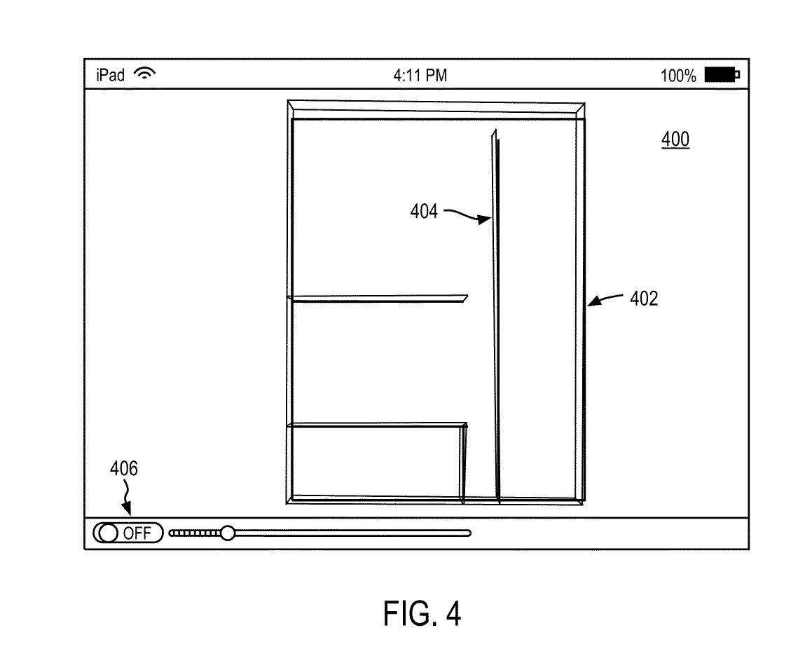

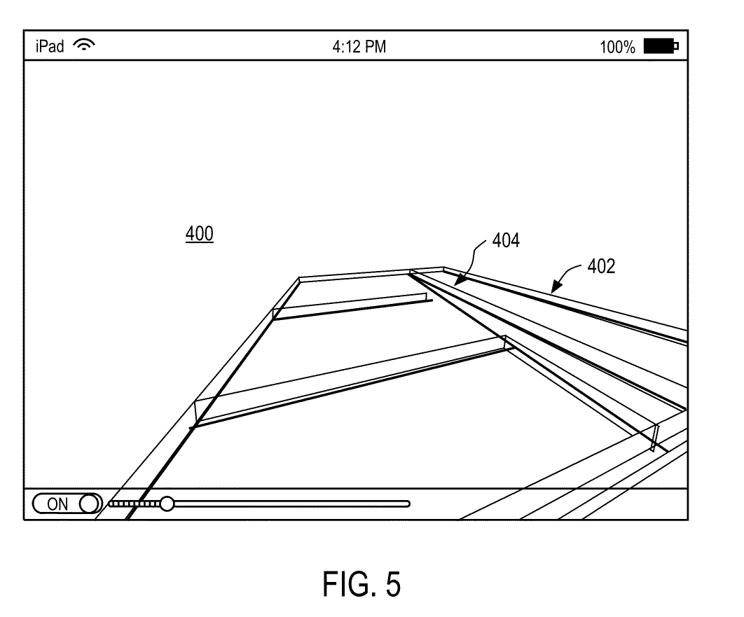

In certain embodiments, an RF environment may be displayed on a device with estimated RF coverage information. FIG. 4 illustrates an RF environment 400 from a top-down, plan view perspective of a building floor plan. An outer wall 402 encloses the building and an inner wall 404 is shown inside the RF environment 400. A view toggle 406 may be provided in the graphical user interface to switch between a plan view and a 3D view or another perspective. FIG. 5 illustrates a 3D view of the RF environment in FIG. 4 that may be displayed after a user selects view toggle 406. The user interface may allow a user to also add, delete or modify the RF environment, for example, by adding, deleting or modifying physical objects including walls, furniture, and other electronics, and RF sources based on touch input, operation key input, voice command, motion commands, etc. In certain embodiments, a user may import a full or partially defined RF environment created using a different tool.

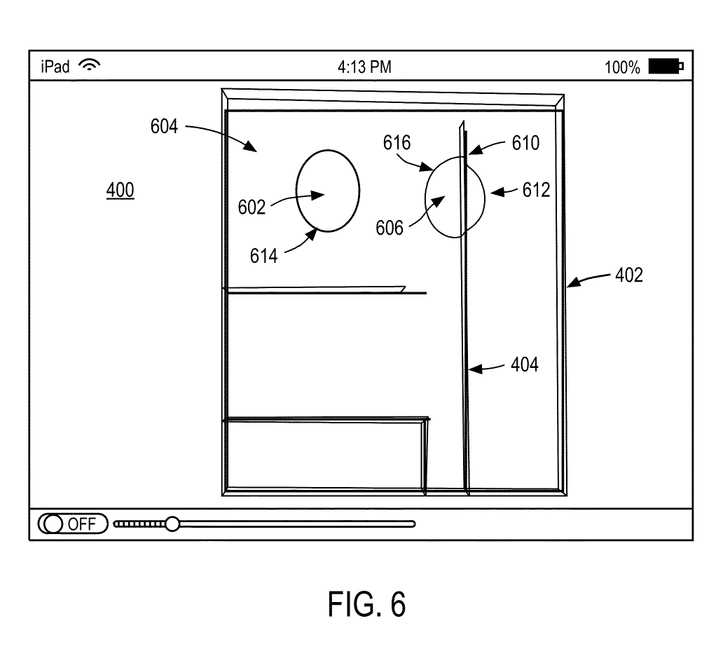

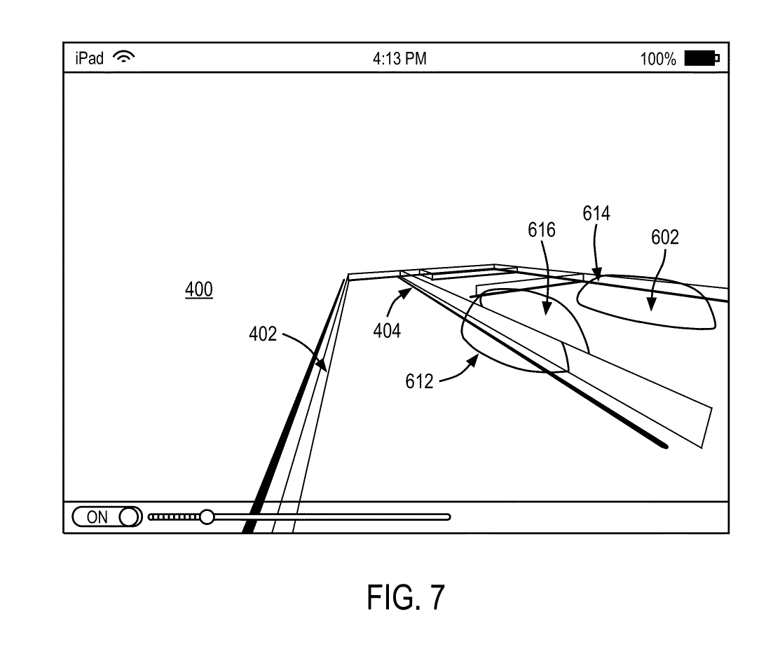

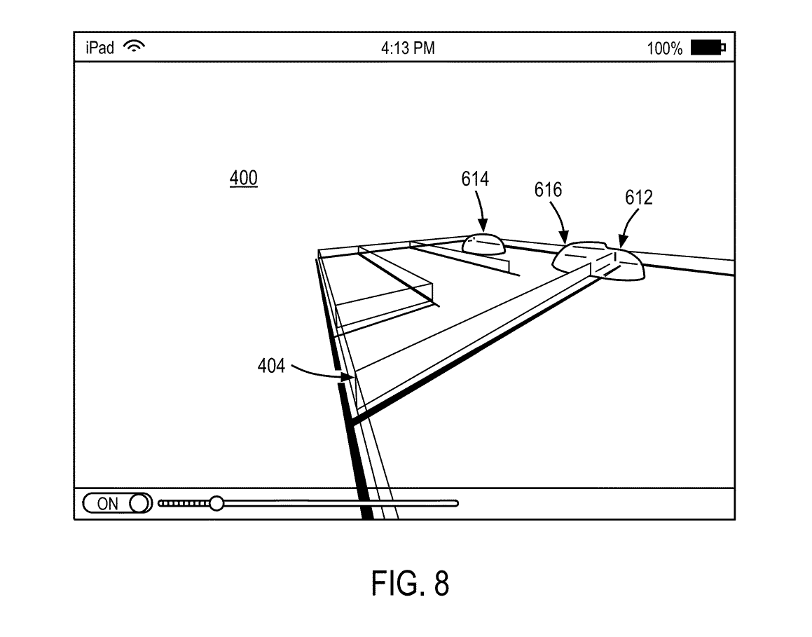

FIG. 6 illustrates another RF environment 400 where two APs are added. First AP 602 provides a corresponding first coverage pattern 614 and is provided in an area 604 with no RF obstacles in the plan view. Second AP 606 provides a corresponding second coverage pattern 616 and is provided in an area 610 including wall 404 that is an RF obstacle. The second coverage pattern 616 is modified to reflect the attenuation caused by intervening wall 404. The effect of the attenuation is illustrated by the attenuated coverage area 612. FIG. 7 illustrates the RF environment 400 in 3D while looking towards attenuated coverage area 612. The 2D and 3D view may be rotated to alter the viewpoint as desired. For example, FIG. 8 illustrates a different 3D vantage point of the RF environment of FIG. 7. In this manner, a user may move virtually through the RF environment 400.

FIG. 9 is a block diagram of exemplar components which may be used to implement some embodiments of the inventions. Thus, the innovations herein may be implemented via one or more components, systems, servers, appliances, other subcomponents, or distributed between such elements. When implemented as a system, such systems may include an/or involve, inter alia, components such as software modules, general-purpose CPU, RAM, etc. found in general-purpose computers. In implementations where the innovations reside on a server, such a server may include or involve components such as CPU, RAM, etc., such as those found in general-purpose computers. In the example in FIG. 9, a network 950 is shown in communication with a server 954 and any number of user devices 958. The network 950 could be any number of local area network, wide area network including the internet. As previously discussed, the user devices could be any number of wired and/or wireless devices, capable of wireless communications. A memory 964 is also shown. The environmental data may be loaded by the server 954 from the data storage 964 to any number of user devices 958 for modeling purposes and for RF data gathering. Further, the user devices, may communicate with any number of example servers 954 and data storage 964 to load modeling information for other users to view and/or manipulate.

### CONCLUSION

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

Additionally, the innovations herein may be achieved via implementations with disparate or entirely different software, hardware and/or firmware components, beyond that set forth above. With regard to such other components (e.g., software, processing components, etc.) and/or computer-readable media associated with or embodying the present inventions, for example, aspects of the innovations herein may be implemented consistent with numerous general purpose or special purpose computing systems or configurations. Various exemplary computing systems, environments, and/or configurations that may be suitable for use with the innovations herein may include, but are not limited to: software or other components within or embodied on personal computers, servers or server computing devices such as routing/connectivity components, hand-held or laptop devices, multiprocessor systems, microprocessor-based systems, set top boxes, consumer electronic devices, network PCs, other existing computer platforms, distributed computing environments that include one or more of the above systems or devices, etc.

Innovative software, circuitry and components herein may also include and/or utilize one or more type of computer readable media. Computer readable media can be any available media that is resident on, associable with, or can be accessed by such circuits and/or computing components. By way of example, and not limitation, computer readable media may comprise computer storage media and communication media. Computer storage media includes volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical storage, magnetic tape, magnetic disk storage or other magnetic storage devices, or any other medium which can be used to store the desired information and can accessed by computing component. Communication media may comprise computer readable instructions, data structures, program modules and/or other components. Further, communication media may include wired media such as a wired network or direct-wired connection, however no media of any such type herein includes transitory media. Combinations of the any of the above are also included within the scope of computer readable media.

In the present description, the terms component, module, device, etc. may refer to any type of logical or functional software elements, circuits, blocks and/or processes that may be implemented in a variety of ways. For example, the functions of various circuits and/or blocks can be combined with one another into any other number of modules. Each module may even be implemented as a software program stored on a tangible memory (e.g., random access memory, read only memory, CD-ROM memory, hard disk drive, etc.) to be read by a central processing unit to implement the functions of the innovations herein. Or, the modules can comprise programming instructions transmitted to a general purpose computer or to processing/graphics hardware via a transmission carrier wave. Also, the modules can be implemented as hardware logic circuitry implementing the functions encompassed by the innovations herein. Finally, the modules can be implemented using special purpose instructions (SIMD instructions), field programmable logic arrays or any mix thereof which provides the desired level performance and cost.

Aspects of the method and system described herein, such as the logic, may also be implemented as functionality programmed into any of a variety of circuitry, including programmable logic devices (“PLDs”), such as field programmable gate arrays (“FPGAs”), programmable array logic (“PAL”) devices, electrically programmable logic and memory devices and standard cell-based devices, as well as application specific integrated circuits. Some other possibilities for implementing aspects include: memory devices, microcontrollers with memory (such as EEPROM), embedded microprocessors, firmware, software, etc. Furthermore, aspects may be embodied in microprocessors having software-based circuit emulation, discrete logic (sequential and combinatorial), custom devices, fuzzy (neural) logic, quantum devices, and hybrids of any of the above device types. The underlying device technologies may be provided in a variety of component types, e.g., metal-oxide semiconductor field-effect transistor (“MOSFET”) technologies like complementary metal-oxide semiconductor (“CMOS”), bipolar technologies like emitter-coupled logic (“ECL”), polymer technologies (e.g., silicon-conjugated polymer and metal-conjugated polymer-metal structures), mixed analog and digital, and so on.

It should also be noted that the various logic and/or functions disclosed herein may be enabled using any number of combinations of hardware, firmware, and/or as data and/or instructions embodied in various machine-readable or computer-readable media, in terms of their behavioral, register transfer, logic component, and/or other characteristics. Computer-readable media in which such formatted data and/or instructions may be embodied include, but are not limited to, non-volatile storage media in various forms (e.g., optical, magnetic or semiconductor storage media) though again does not include transitory media. Unless the context clearly requires otherwise, throughout the description, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list. Although certain presently preferred implementations of the invention have been specifically described herein, it will be apparent to those skilled in the art to which the invention pertains that variations and modifications of the various implementations shown and described herein may be made without departing from the spirit and scope of the invention. Accordingly, it is intended that the invention be limited only to the extent required by the applicable rules of law.

What is claimed is:

1. A method of modeling a radio frequency (RF) coverage pattern by a processor, comprising the steps of:
receiving coverage pattern 104 data of an RF source 102 and environment data where the RF source is placed;
determining a set of obstructed coordinates of the coverage pattern based on a location of an obstacle between the RF source and a coverage pattern surface; and
determining a modified RF coverage pattern of the RF source by modifying the set of obstructed coordinates based on an attenuation factor of the obstacle.

2. The method of claim 1, wherein the coverage pattern data includes a plurality of vertices.

3. The method of claim 1, wherein a coordinate of the coverage pattern data is included in the set of obstructed coordinates when the obstacle intersects a line segment formed from the RF source to the coordinate.

4. The method of claim 1, wherein the set of coordinates are moved towards the RF source.

5. The method of claim 1, further comprising:
determining an attenuation factor of the obstacle based on at least one of shape, material and reflection.

6. The method of claim 1, wherein the coverage pattern corresponds to at least one signal characteristic of an RF source including transmission signal strength, received signal strength, throughput, and reception sensitivity.

7. A computer storage storing a sequence of instructions that, when executed by a computer processor, cause the computer processor to perform a method of modeling a radio frequency (RF) coverage pattern comprising:
receiving coverage pattern data of an RF source and environment data where the RF source is placed;
determining a set of obstructed coordinates of the coverage pattern data based on an obstacle of the environment being between the RF source and the coverage pattern; and
determining a modified RF coverage pattern of the RF source by changing the set of obstructed coordinates based on an attenuation factor of the obstacle.

8. The instructions of claim 7, wherein the coverage pattern data includes a plurality of vertices.

9. The instructions of claim 7, wherein a coordinate of the coverage pattern data is included in the set of obstructed coordinates when the obstacle intersects a line segment formed from the RF source to the coordinate.

10. The instructions of claim 7, wherein the set of coordinates are moved towards the RF source.

11. The instructions of claim 7, further comprising:
determining an attenuation factor of the obstacle based on at least one of shape, material and reflection.

12. The instructions of claim 7, wherein the coverage pattern corresponds to at least one signal characteristic of an RF source including transmission signal strength, received signal strength, throughput, and reception sensitivity.

13. A radio frequency (RF) coverage modeling system, comprising:
a processor configured to,
determine a set of obstructed coordinates of the coverage pattern based on an obstacle of the environment being between an RF source and the coverage pattern and that determines a modified RF coverage pattern of the RF source by changing the set of obstructed coordinates based on an attenuation factor of the obstacle;
receive coverage pattern data of an RF source and environment data where the RF source is placed;
cause display of a user interface including information about the RF source, the environment and the RF coverage pattern.

14. The system of claim 13, wherein the processor is configured to cause display of two-dimensional perspective and a three-dimensional perspective.

15. The system of claim 13, wherein the processor is further configured to receive at least one touch input, operation key input, voice input and motion input.

16. The system of claim 13, wherein the processor is further configured to receive input that modifies any of the RF source and the obstacles of the environment.

17. The system of claim 16, wherein the processor is configured to redetermine the modified RF coverage pattern based on the modifications.

18. The system of claim 14, wherein the processor is further configured to determine the modified RF coverage pattern of a two-dimensional cross-section for the two-dimensional perspective.

19. The system of claim 13, wherein the coverage pattern data of the RF source and the environment data are received from another device over a communication network.

20. The system of claim 13, wherein the coverage pattern data includes a plurality of vertices.
